(19) United States
(12) Patent Application Publication
(10) Pub. No.: US 2020/0214173 A1
(43) Pub. Date: Jul. 2, 2020

(54) PHASE-CHANGE COOLING APPARATUS AND PHASE-CHANGE COOLING METHOD

(71) Applicant: NEC CORPORATION, Tokyo (JP)

(72) Inventors: Masanori SATO, Tokyo (JP); Koichi TODOROKI, Tokyo (JP); Minoru YOSHIKAWA, Tokyo (JP)

(73) Assignee: NEC CORPORATION, Tokyo (JP)

(21) Appl. No.: 16/631,323

(22) PCT Filed: Jul. 13, 2018
(86) PCT No.: PCT/JP2018/026536

§ 371 Date: Jan. 15, 2020

(30) Foreign Application Priority Data
Jul. 18, 2017 (JP) 2017-139149

(51) Int. Cl. H05K 7/20; F28D 15/02; F28D 15/06

(52) U.S. Cl. CPC H05K 7/20381; F28D 15/02; F28D 15/06; H05K 7/20327; H05K 7/20309; H05K 7/20318; F28D 15/025

(57) ABSTRACT

A phase-change cooling apparatus according to an exemplary aspect of the present invention includes heat receiving means; refrigerant liquid driving means for circulating the refrigerant liquid; a first refrigerant flow path in which the refrigerant liquid flowing away from the refrigerant liquid driving means circulates through the heat receiving means and the heat radiating means; a second refrigerant flow path of a flow path shortening the first refrigerant flow path in such a way that a branched refrigerant liquid being at least part of the refrigerant liquid flowing away from the refrigerant liquid driving means toward the heat receiving means circulates without passing through the heat receiving means and the heat radiating means; and control means for controlling a flow rate of a heat-receiving-side refrigerant liquid being a refrigerant liquid flowing into the heat receiving means based on a flow rate of the branched refrigerant liquid.

### TECHNICAL FIELD

The present invention relates to phase-change cooling apparatuses and phase-change cooling methods that are used for cooling electronic equipment and the like and, in particular, to a phase-change cooling apparatus and a phase-change cooling method in which refrigerant liquid is circulated using a driving source.

### BACKGROUND ART

In recent years, as electronic equipment has been miniaturized and sophisticated, the heating value and the heating density have been increasing. In order to cool such electronic equipment and the like efficiently, it is necessary to adopt a cooling system with high cooling capacity. As one of cooling systems with high cooling capacity, a phase-change cooling system using a phase change of a refrigerant has attracted attention.

One example of a cooling device using the phase-change cooling system (phase-change cooling apparatus) is described in Patent Literature 1 (PTL 1). A cooling module for an electronic apparatus described in PTL 1 is a pump-circulation-type phase-change cooling apparatus and includes a jacket (heat receiving section) thermally connected to a heating element and absorbing heat, a radiator, a tank having a gas-liquid separating function, and a cooling liquid driving unit constituted by an electric pump.

An inlet of the jacket is provided with a pipe through which a refrigerant flows in a liquid state, and an outlet of the jacket is provided with a pipe through which a gas-liquid mixture flows. The cooling liquid driving unit is mounted in front of an inlet pipe of the jacket, and the tank having a gas-liquid separating function is connected to the vicinity of the outlet of the jacket. The refrigerant steam separated by the tank flows into a steam pipe, and then is condensed by the radiator and returns to the cooling liquid drive unit via a pipe, thereby forming a closed loop of the refrigerant.

The tank having the gas-liquid separating function is partitioned by a porous body into a region in which the refrigerant liquid is held, and a gas-liquid mixing region in which the refrigerant in the gas-liquid mixed state sucked from the jacket is present. The region in which the refrigerant liquid is held is connected between the radiator and the cooling liquid driving means by a bypass pipe.

It is said that, according to the related cooling module (phase-change cooling apparatus), the configurations make it possible to reduce the adhesion of the refrigerant liquid in the pipe between the jacket and the radiator; as a result, reduce the pressure loss between the jacket and the radiator, thereby perform efficient cooling.

Patent Literature 2 (PTL 2) discloses a related cooling system for an electronic equipment device including, between an evaporator and a condenser, a refrigerant natural circulation mechanism and a refrigerant forced circulation mechanism that are switchable.

The related cooling system for an electric device includes a gas pipe from the evaporator to the condenser, a liquid pipe from the condenser to the evaporator, a bypass pipe provided in an intermediate part of the liquid pipe, and a pump provided in the bypass pipe. The related cooling system for an electric device further includes a check valve provided in a bypass corresponding part of the liquid pipe, a tank provided on an upstream side of the liquid pipe in communication with the liquid pipe, a temperature sensor for measuring an exhaust temperature after cooling the exhaust heat air by the evaporator, and a controller. The controller is configured to drive the pump when a measured temperature of the temperature sensor becomes higher than a set temperature for stopping natural circulation, and stop the pump when the measured temperature decreases.

It is said that, according to the related cooling system for an electric device, the above-described configurations make it possible to shorten the time of the forced circulation so as not to stop the natural circulation as much as possible, and to perform stable operation by smoothly switching from natural circulation to the forced circulation.

The related art also includes a technique described in Patent Literature 3 (PTL 3).

### CITATION LIST

### Patent Literature

[PTL 1] Japanese Unexamined Patent Application Publication No. 2008-130746

[PTL 2] Japanese Unexamined Patent Application Publication No. 2010-190553

[PTL 3] Japanese Unexamined Patent Application Publication No. 2012-059276

### SUMMARY OF INVENTION

### Technical Problem

As with the related, above-mentioned cooling modules (systems) described in Patent Literature 1 and Patent Literature 2, a pump-circulation-type phase-change cooling apparatus in which a refrigerant liquid is circulated using a driving source such as a pump has the problem that the cooling capacity is significantly reduced immediately after startup. The reason will be described below.

In the pump-circulation-type phase-change cooling apparatus, the action of gravity causes the refrigerant liquid to collect in a heat receiving section and a steam pipe when a pump has stopped. Then, when the pump is restarted, the evaporation of the refrigerant liquid in the heat receiving section is suppressed due to the pressure of a liquid column of the refrigerant liquid collecting in the steam pipe; consequently, the heat receiving section receives the heat through the sensible heat of the refrigerant liquid. The refrigerant flowing into a heat radiation section in a liquid-phase state is cooled in the heat radiation section and flows back to the heat receiving section. This prevents the temperature of the refrigerant liquid from rising up to the boiling point; accordingly, the heat receiving section performs the cooling not by the latent heat of the evaporation but by the sensible heat of the refrigerant liquid. In such a case, the cooling capacity of the pump-circulation-type phase-change cooling apparatus is significantly reduced because the heat receiving through the sensible heat is generally less efficient than the heat receiving through the latent heat.

As described above, a phase-change cooling apparatus circulating a refrigerant liquid using a driving source has the problem that the cooling capacity is significantly reduced immediately after startup.

An object of the present invention is to provide a phase-change cooling apparatus and a phase-change cooling method that solve the above-mentioned problem that the cooling capacity of a phase-change cooling apparatus circulating a refrigerant liquid using a driving source is significantly reduced immediately after startup.

### Solution to Problem

A phase-change cooling apparatus according to an exemplary aspect of the present invention includes heat receiving means for holding a refrigerant liquid to receive heat from a heat-generating source; heat radiating means for releasing heat of refrigerant vapor produced by evaporation of the refrigerant liquid in the heat receiving means and producing the refrigerant liquid; refrigerant liquid driving means for circulating the refrigerant liquid; a first refrigerant flow path in which the refrigerant liquid flowing away from the refrigerant liquid driving means circulates through the heat receiving means and the heat radiating means; a second refrigerant flow path of a flow path shortening the first refrigerant flow path in such a way that a branched refrigerant liquid being at least part of the refrigerant liquid flowing away from the refrigerant liquid driving means toward the heat receiving means circulates without passing through the heat receiving means and the heat radiating means; and control means for controlling a flow rate of a heat-receiving-side refrigerant liquid being a refrigerant liquid flowing into the heat receiving means based on a flow rate of the branched refrigerant liquid.

A phase-change cooling method according to an exemplary aspect of the present invention includes circulating a refrigerant liquid flowing away from refrigerant liquid driving means in a first refrigerant flow path through heat receiving means and heat radiating means; circulating a branched refrigerant liquid being at least part of the refrigerant liquid flowing away from the refrigerant liquid driving means toward the heat receiving means through a second refrigerant flow path shortening the first refrigerant flow path, without passing through the heat receiving means and the heat radiating means; and controlling a flow rate of a heat-receiving-side refrigerant liquid being the refrigerant liquid flowing into the heat receiving means based on a flow rate of the branched refrigerant liquid.

### Advantageous Effects of Invention

According to the phase-change cooling apparatus and the phase-change cooling method of the present invention, it is possible to avoid a decrease in cooling capacity immediately after startup even though a refrigerant liquid is circulated using a driving source.

### BRIEF DESCRIPTION OF DRAWINGS

FIG. 1 is a schematic view schematically illustrating a configuration of a phase-change cooling apparatus according to a first example embodiment of the present invention.

FIG. 2 is a schematic view schematically illustrating a configuration of a phase-change cooling apparatus according to a second example embodiment of the present invention.

FIG. 3 is a block diagram illustrating a configuration of a controller included in the phase-change cooling apparatus according to the second example embodiment of the present invention.

FIG. 4 is a schematic view schematically illustrating a configuration of a phase-change cooling apparatus according to a third example embodiment of the present invention.

FIG. 5 is a block diagram illustrating a configuration of a controller included in the phase-change cooling apparatus according to the third example embodiment of the present invention.

FIG. 6 is a schematic view schematically illustrating another configuration of the phase-change cooling apparatus according to the third example embodiment of the present invention.

FIG. 7 is a schematic view schematically illustrating yet another configuration of the phase-change cooling apparatus according to the third example embodiment of the present invention.

FIG. 8 is a schematic view schematically illustrating a configuration of a phase-change cooling apparatus according to a fourth example embodiment of the present invention.

FIG. 9 is a block diagram illustrating a configuration of a controller included in the phase-change cooling apparatus according to the fourth example embodiment of the present invention.

FIG. 10 is a schematic view schematically illustrating a configuration of a phase-change cooling apparatus according to a fifth example embodiment of the present invention.

FIG. 11 is a block diagram illustrating a configuration of a controller included in the phase-change cooling apparatus according to the fifth example embodiment of the present invention.

FIG. 12 is a schematic view schematically illustrating another configuration of the phase-change cooling apparatus according to the fifth example embodiment of the present invention.

FIG. 13 is a block diagram illustrating another configuration of the controller included in the phase-change cooling apparatus according to the fifth example embodiment of the present invention.

FIG. 14 is a schematic view schematically illustrating a configuration of a phase-change cooling apparatus according to a sixth example embodiment of the present invention.

FIG. 15 is a block diagram illustrating a configuration of a controller included in the phase-change cooling apparatus according to the sixth example embodiment of the present invention.

### EXAMPLE EMBODIMENT

Example embodiments of the present invention will be described with reference to drawings below.

### First Example Embodiment

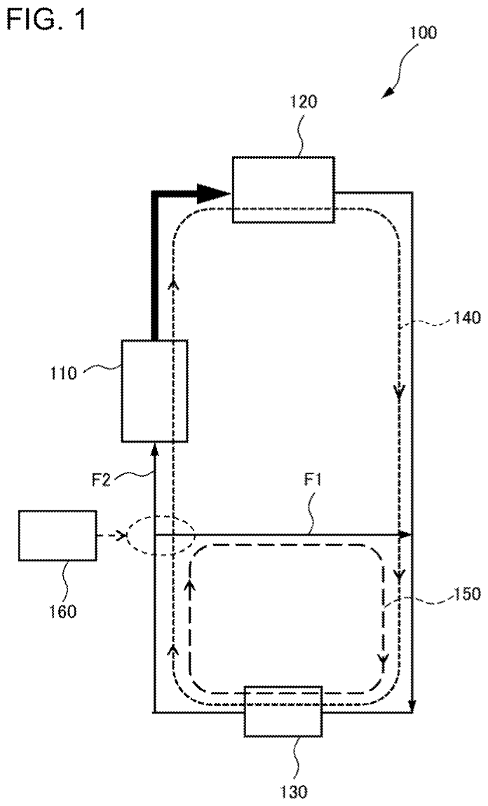

FIG. 1 is a schematic view schematically illustrating a configuration of a phase-change cooling apparatus 100 according to a first example embodiment of the present invention.

The phase-change cooling apparatus 100 according to the present example embodiment includes a heat receiver (heat receiving means) 110, a heat radiator (heat radiating means) 120, a refrigerant liquid driving section (refrigerant liquid driving means) 130, a first refrigerant flow path 140, a second refrigerant flow path 150, and a controller (control means) 160.

The heat receiver 110 holds a refrigerant liquid to receive heat from a heat-generating source. The heat radiator 120 releases heat of refrigerant vapor produced by evaporation of the refrigerant liquid in the heat receiver 110 and produces the refrigerant liquid. The refrigerant liquid driving section 130 circulates the refrigerant liquid.

The refrigerant liquid flowing away from the refrigerant liquid driving section 130 circulates in the first refrigerant flow path 140 through the heat receiver 110 and the heat radiator 120. The second refrigerant flow path 150 is a flow path shortening the first refrigerant flow path 140 in such a way that a branched refrigerant liquid F1 that is at least part of the refrigerant liquid flowing away from the refrigerant liquid driving section 130 toward the heat receiver 110 circulates without passing through the heat receiver 110 and the heat radiator 120. The controller 160 controls a flow rate of a heat-receiving-side refrigerant liquid F2 that is a refrigerant liquid flowing into the heat receiver 110, based on a flow rate of the branched refrigerant liquid F1.

As described above, the phase-change cooling apparatus 100 of the present example embodiment includes the second refrigerant flow path 150 in which at least part of the refrigerant liquid (branched refrigerant liquid F1) circulates without passing through the heat receiver 110 and the heat radiator 120. The phase-change cooling apparatus 100 is configured to control the flow rate of the heat-receiving-side refrigerant liquid F2 flowing into the heat receiver 110 based on the flow rate of the branched refrigerant liquid F1. These configurations make it possible to supply the heat receiver 110 with the heat-receiving-side refrigerant liquid F2 having an optimum flow rate according to the amount of heat to be received from the heat-generating source. This causes no refrigerant liquid to remain between the heat receiver 110 and the heat radiator 120; therefore, it is possible to avoid a decrease in cooling capacity at restart.

Next, a phase-change cooling method according to the present example embodiment will be described.

In the phase-change cooling method according to the present example embodiment, first, a refrigerant liquid flowing away from a refrigerant liquid driving section (refrigerant liquid driving means) is circulated in a first refrigerant flow path through a heat receiver (heat receiving means) and a heat radiator (heat radiating means). A branched refrigerant liquid that is at least part of the refrigerant liquid flowing away from the refrigerant liquid driving section toward the heat receiver, is circulated through a second refrigerant flow path shortening the first refrigerant flow path, without passing through the heat receiver and the heat radiator. A flow rate of a heat-receiving-side refrigerant liquid that is a refrigerant liquid that flowing into the heat receiver is controlled based on a flow rate of the branched refrigerant liquid.

At this time, in controlling the flow rate of the heat-receiving-side refrigerant liquid, the flow rate of the refrigerant liquid flowing away from the refrigerant liquid driving section can be controlled with the flow rate of the branched refrigerant liquid holding constant. Alternatively, in controlling the flow rate of the heat-receiving-side refrigerant liquid, the flow rate of the branched refrigerant liquid may be controlled.

As mentioned above, according to the phase-change cooling apparatus 100 and the phase-change cooling method of the present example embodiment, it is possible to avoid a decrease in cooling capacity immediately after startup even though a refrigerant liquid is circulated using a driving source.

### Second Example Embodiment

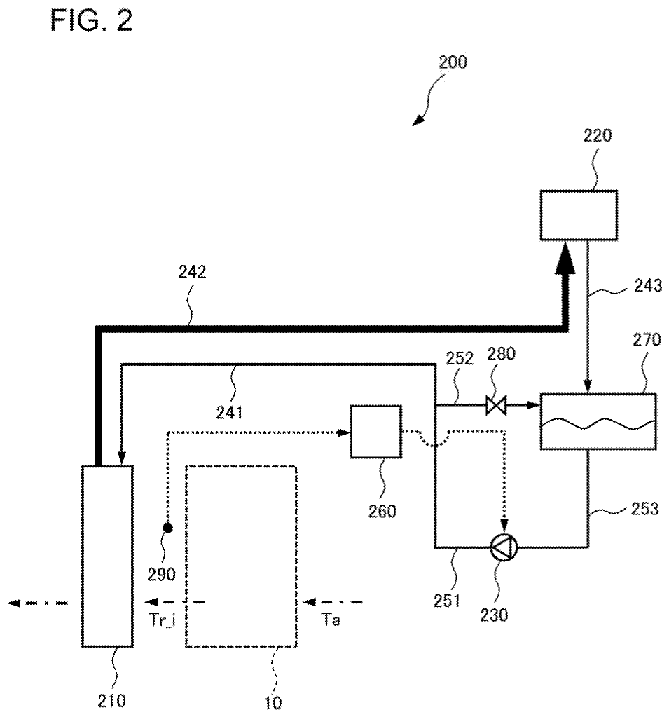

Next, a second example embodiment of the present invention will be described. FIG. 2 schematically illustrates a configuration of a phase-change cooling apparatus 200 according to the second example embodiment of the present invention.

The phase-change cooling apparatus 200 according to the present example embodiment includes a heat receiver (heat receiving means) 210, a heat radiator (heat radiating means) 220, a pump 230 serving as a refrigerant liquid driving means, and a controller (control means) 260. The heat receiver 210 holds a refrigerant liquid internally, and the refrigerant liquid boils receiving exhaust heat of electronic equipment 10 and. The heat radiator 220 cools a vapor-phase refrigerant that has boiled and vaporized in the heat receiver 210. The pump 230 circulates the refrigerant liquid.

The phase-change cooling apparatus 200 of the present example embodiment is configured to include further a tank 270 serving as a refrigerant storing means for storing the refrigerant liquid, and a constant flow valve 280. The constant flow valve 280 controls the flow rate of a branched refrigerant liquid that is at least part of the refrigerant liquid flowing away from the pump 230 toward the heat receiver 210, so as to be maintained constant. The pump 230 serving as the refrigerant liquid driving means has the function that its flow rate varies according to its rotation frequency. The controller 260 controls the rotation frequency of the pump 230, which causes the flow rate of a heat-receiving-side refrigerant liquid flowing into the heat receiver 210 to be controlled.

The pump 230 and the heat receiver 210 are connected by a first liquid pipe 251 and a second liquid pipe 241, and the heat receiver 210 and the heat radiator 220 are connected by a steam pipe 242. The heat radiator 220 and the tank 270 are connected by a third liquid pipe 243, and the tank 270 and the pump 230 are connected by a fourth liquid pipe 253. A fifth liquid pipe 252 connects the tank 270 to the first liquid pipe 251 and the second liquid pipe 241.

A first refrigerant flow path is composed of the first liquid pipe 251, the second liquid pipe 241, the steam pipe 242, the third liquid pipe 243, and the fourth liquid pipe 253. A second refrigerant flow path is composed of the first liquid pipe 251, the fifth liquid pipe 252, and the fourth liquid pipe 253. The constant flow valve 280 is disposed on the fifth liquid pipe 252 in the second refrigerant flow path. The tank 270 is disposed in a flow path common to the first refrigerant flow path and the second refrigerant flow path.

The phase-change cooling apparatus 200 according to the present example embodiment is configured to control the flow rate of the heat-receiving-side refrigerant liquid by the controller 260, based on a heat-receiving-side measured value regarding the amount of heat received from the electronic equipment 10 serving as a heat-generating source. In this case, the heat-receiving-side measured value can be an output value of a temperature sensor to detect the temperature of the exhaust air from the heat-generating source. In other words, the present example embodiment is configured to dispose a temperature sensor 290 on the exhaust side of the electronic equipment 10 serving as the heat-generating source. Here, an output value of the temperature sensor 290 is represented by Tr_i. A corresponding value on the intake side of the electronic equipment 10 is represented by Ta.

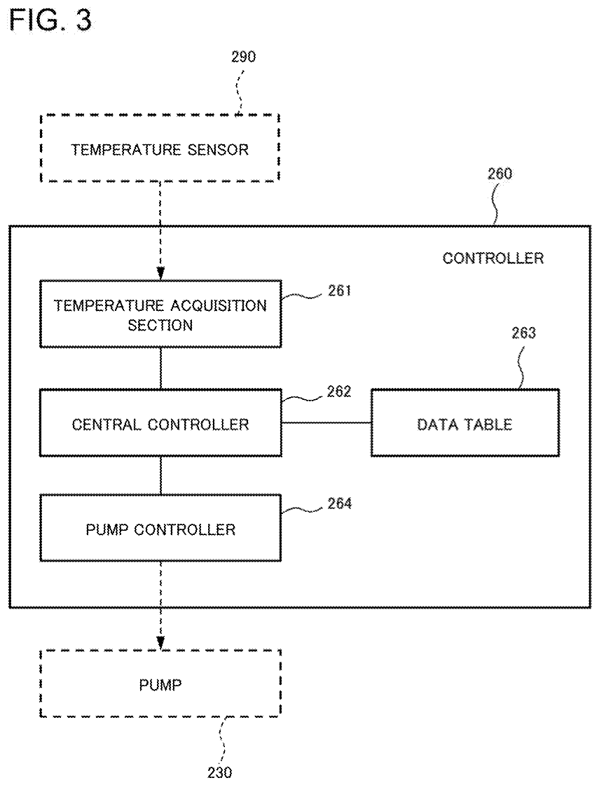

FIG. 3 illustrates a configuration of the controller 260 included in the phase-change cooling apparatus 200 according to the present example embodiment. The controller 260 includes a temperature acquisition section 261 configured to acquire the output value Tr_i from the temperature sensor 290, a central controller 262, a data table 263 configured to record a reference value of the output value of the temperature sensor 290, and a pump controller 264 configured to control the pump 230.

Next, the operations of the controller 260 included in the phase-change cooling apparatus 200 according to the present example embodiment will be described.

The temperature acquisition section 261 included in the controller 260 acquires the output value Tr_i from the temperature sensor 290. The central controller 262 determines, from the output value Tr_i and the reference value recorded in the data table 263, whether or not to vary the rotation frequency of the pump 230 from a specified value. If the output value Tr_i is greater than T_base serving as a baseline, the pump 230 is controlled through the pump controller 264 in such a way that the rotation frequency of the pump 230 becomes greater than the specified value. On the other hand, if the output value Tr_i is smaller than T_base, the pump 230 is controlled in such a way that the rotation frequency of the pump 230 becomes smaller than the specified value.

If the output value Tr_i from the temperature sensor 290 is smaller than a threshold value Tth, the controller 260 reduces the rotation frequency of the pump 230 so that all the refrigerant liquid can circulate through the fifth liquid pipe 252 without the refrigerant liquid supplied to the heat receiver 210. At this time, if the output value Tr_i from the temperature sensor 290 has been smaller than the threshold value Tth over a given period of time, the pump 230 is stopped, which makes it possible to save energy.

As mentioned above, the phase-change cooling apparatus 200 according to the present example embodiment circulates the refrigerant by the pump 230 serving as the driving source, and cools the electronic equipment 10 utilizing a phase-change phenomenon of the refrigerant. At this time, a variation in the heating value of the electronic equipment 10 is detected from the information on the exhaust temperature of the electronic equipment 10 that is obtained by the temperature sensor 290, and the rotation frequency of the pump 230 is controlled by an inverter or the like depending on the variation in the heating value.

The above-described configurations make it possible to vary the flow rate of the refrigerant liquid to be supplied for the heat receiver 210. This makes it possible to supply the heat receiver 210 with the refrigerant liquid having the optimum flow rate according to the heating value. As a result, it can be avoided that the refrigerant liquid remains within the steam pipe 242 connecting the heat receiver 210 and the heat radiator 220.

If the heating value of the electronic equipment 10 is very small, the flow rate of the refrigerant liquid that the pump 230 sends out is controlled to be a flow rate equal to or less than a set value of the constant flow valve 280, which enables no refrigerant liquid to be supplied to the heat receiver 210. Accordingly, in this case, no refrigerant liquid remains in the steam pipe 242.

As described above, according to the phase-change cooling apparatus 200 of the present example embodiment, it is possible to avoid a decrease in cooling capacity at restart.

In the above example embodiment, the configuration is described in which the constant flow valve 280 is disposed on the fifth liquid pipe 252. However, without applying only to this, instead of the constant flow valve 280, a check valve can be used whose forward direction is a direction from the first liquid pipe 251 toward the tank 270. In this case, it is possible, by inserting an orifice or a throttle structure into the fifth liquid pipe 252, to supply the refrigerant liquid also to the heat receiver 210 when the rotation frequency of the pump 230 is increased.

Next, a phase-change cooling method according to the present example embodiment will be described.

In the phase-change cooling method according to the present example embodiment, first, a refrigerant liquid flowing away from a refrigerant liquid driving section (refrigerant liquid driving means) is circulated in a first refrigerant flow path through a heat receiver (heat receiving means) and a heat radiator (heat radiating means). A branched refrigerant liquid that is at least part of the refrigerant liquid flowing away from the refrigerant liquid driving section toward the heat receiver, is circulated through a second refrigerant flow path shortening the first refrigerant flow path, without passing through the heat receiver and the heat radiator. A flow rate of a heat-receiving-side refrigerant liquid that is a refrigerant liquid that flowing into the heat receiver is controlled based on a flow rate of the branched refrigerant liquid. The configurations so far are similar to those of the phase-change cooling method according to the first example embodiment.

In the phase-change cooling method according to the present example embodiment, in controlling the flow rate of the heat-receiving-side refrigerant liquid, the flow rate of the refrigerant liquid flowing away from the refrigerant liquid driving section is controlled with the flow rate of the branched refrigerant liquid holding constant. Then the flow rate of the refrigerant liquid is controlled based on a heat-receiving-side measured value regarding the amount of heat received from a heat-generating source.

As mentioned above, according to the phase-change cooling apparatus 200 and the phase-change cooling method of the present example embodiment, it is possible to avoid a decrease in cooling capacity immediately after startup even though a refrigerant liquid is circulated using a driving source.

### Third Example Embodiment

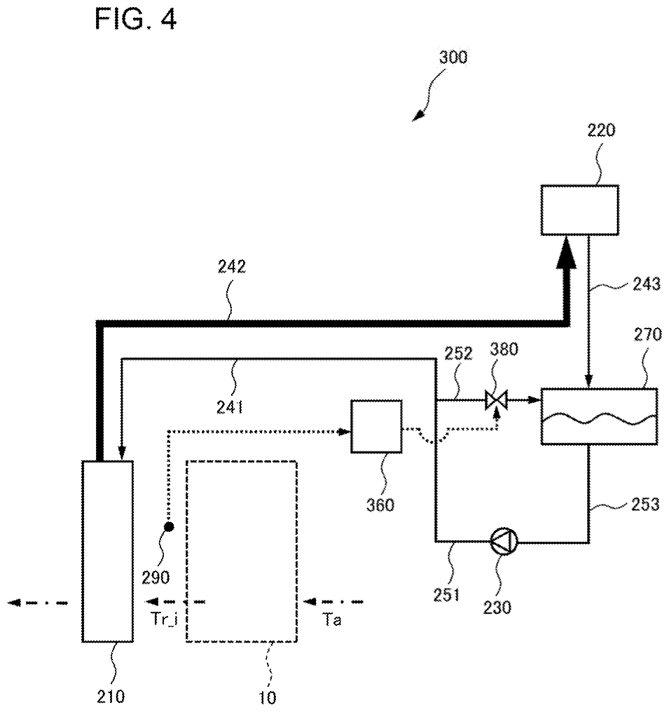

Next, a third example embodiment of the present invention will be described. FIG. 4 schematically illustrates a configuration of a phase-change cooling apparatus 300 according to the third example embodiment of the present invention. The identical reference sign is assigned to a configuration similar to that of the phase-change cooling apparatus 200 according to the second example embodiment, and its detailed description is not repeated.

The phase-change cooling apparatus 300 according to the present example embodiment includes a heat receiver (heat receiving means) 210, a heat radiator (heat radiating means) 220, a pump 230 serving as a refrigerant liquid driving means, a tank 270 serving as a refrigerant storing means, and a controller (control means) 360. The phase-change cooling apparatus 300 of the present example embodiment further includes a branched flow control valve 380.

The branched flow control valve 380 controls the flow rate of a branched refrigerant liquid that is at least part of the refrigerant liquid flowing away from the pump 230 toward the heat receiver 210. The branched flow control valve 380 is disposed on a fifth liquid pipe 252 in a second refrigerant flow path. The second refrigerant flow path is composed of a first liquid pipe 251, the fifth liquid pipe 252, and a fourth liquid pipe 253. The controller 360 controls the branched flow control valve, which causes the flow rate of a heat-receiving-side refrigerant liquid flowing into the heat receiver 210 to be controlled.

The phase-change cooling apparatus 300 according to the present example embodiment is configured to control the flow rate of the heat-receiving-side refrigerant liquid by the controller 360, based on a heat-receiving-side measured value regarding the amount of heat received from electronic equipment 10 serving as a heat-generating source. In this case, the heat-receiving-side measured value can be an output value of a temperature sensor to detect the temperature of the exhaust air from the heat-generating source. In other words, the present example embodiment is configured to dispose a temperature sensor 290 on the exhaust side of the electronic equipment 10 serving as the heat-generating source. Here, an output value of the temperature sensor 290 is represented by Tr_i. A corresponding value on the intake side of the electronic equipment 10 is represented by Ta.

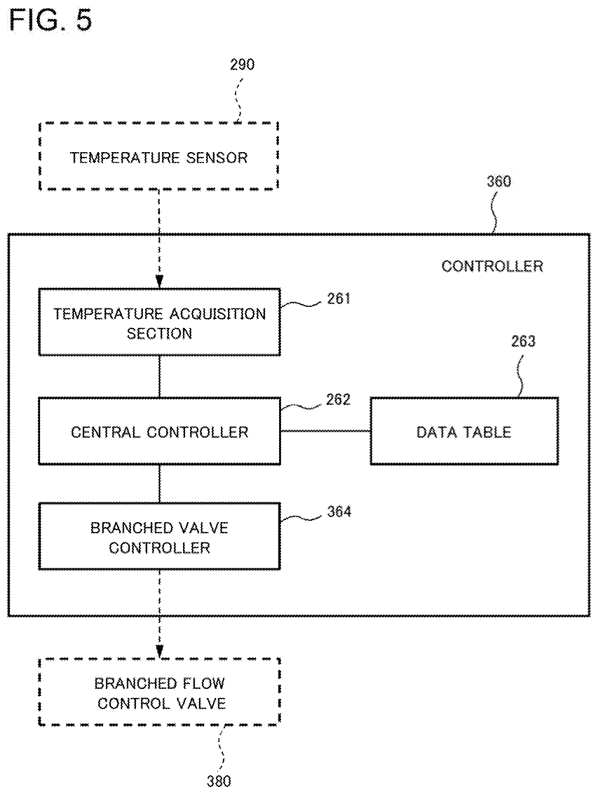

FIG. 5 illustrates a configuration of the controller 360 included in the phase-change cooling apparatus 300 according to the present example embodiment. The controller 360 includes a temperature acquisition section 261 configured to acquire the output value Tr_i from the temperature sensor 290, a central controller 262, a data table 263 in which a reference value of the output value of the temperature sensor 290 is recorded, and a branched valve controller 364 configured to control the branched flow control valve 380.

Next, the operations of the controller 360 included in the phase-change cooling apparatus 300 according to the present example embodiment will be described.

The temperature acquisition section 261 included in the controller 360 acquires the output value Tr_i from the temperature sensor 290. The central controller 262 determines, from the output value Tr_i and the reference value recorded in the data table 263, an opening degree of the branched flow control valve 380. That is to say, the central controller 262 compares the output value Tr_i of the temperature sensor 290 with the reference value; as a result, if the heating value of the electronic equipment 10 is judged as large, the central controller 262 sets the branched flow control valve 380 to a small opening degree, through the branched valve controller 364. This enables the flow rate of the heat-receiving-side refrigerant liquid flowing into the heat receiver 210 to increase. On the other hand, if the heating value of the electronic equipment 10 is judged as small, the central controller 262 sets the branched flow control valve 380 to a large opening degree, through the branched valve controller 364. This enables the flow rate of the heat-receiving-side refrigerant liquid flowing into the heat receiver 210 to decrease.

As described above, the phase-change cooling apparatus 300 according to the present example embodiment is configured to detect a variation in the heating value of the electronic equipment 10 from the information on the exhaust temperature of the electronic equipment 10 that is obtained by the temperature sensor 290, and control the opening degree of the branched flow control valve 380 depending on the variation in the heating value. The above-described configurations make it possible to vary the flow rate of the refrigerant liquid to be supplied for the heat receiver 210 depending on the heating value of the electronic equipment 10. This makes it possible to supply the heat receiver 210 with the refrigerant liquid having the optimum flow rate according to the heating value. As a result, it can be avoided that the refrigerant liquid remains within the steam pipe 242 connecting the heat receiver 210 and the heat radiator 220.

If the heating value of the electronic equipment 10 is very small, the opening degree of the branched flow control valve 380 is controlled to be a fully open condition, for example, which enables no refrigerant liquid to be supplied to the heat receiver 210. Accordingly, in this case, no refrigerant liquid remains in the steam pipe 242.

As described above, according to the phase-change cooling apparatus 300 of the present example embodiment, it is possible to avoid a decrease in cooling capacity at restart.

Next, a phase-change cooling method according to the present example embodiment will be described.

In the phase-change cooling method according to the present example embodiment, first, a refrigerant liquid flowing away from a refrigerant liquid driving section (refrigerant liquid driving means) is circulated in a first refrigerant flow path through a heat receiver (heat receiving means) and a heat radiator (heat radiating means). A branched refrigerant liquid that is at least part of the refrigerant liquid flowing away from the refrigerant liquid driving section toward the heat receiver, is circulated through a second refrigerant flow path shortening the first refrigerant flow path, without passing through the heat receiver and the heat radiator. A flow rate of a heat-receiving-side refrigerant liquid that is a refrigerant liquid that flowing into the heat receiver is controlled based on a flow rate of the branched refrigerant liquid. The configurations so far are similar to those of the phase-change cooling method according to the first example embodiment.

In the phase-change cooling method according to the present example embodiment, in controlling the flow rate of the heat-receiving-side refrigerant liquid, the flow rate of the branched refrigerant liquid is controlled. Then the flow rate of the branched refrigerant liquid is controlled based on a heat-receiving-side measured value regarding the amount of heat received from a heat-generating source.

As mentioned above, according to the phase-change cooling apparatus 300 and the phase-change cooling method of the present example embodiment, it is possible to avoid a decrease in cooling capacity immediately after startup even though a refrigerant liquid is circulated using a driving source.

In the above example embodiments, the controller is configured to control the flow rate of the heat-receiving-side refrigerant liquid based on the heat-receiving-side measured value regarding the amount of heat received from the electronic equipment 10 serving as the heat-generating source. The above example embodiments have been described in which the heat-receiving-side measured value is the output value of the temperature sensor 290 to detect the temperature of the exhaust air from the heat-generating source.

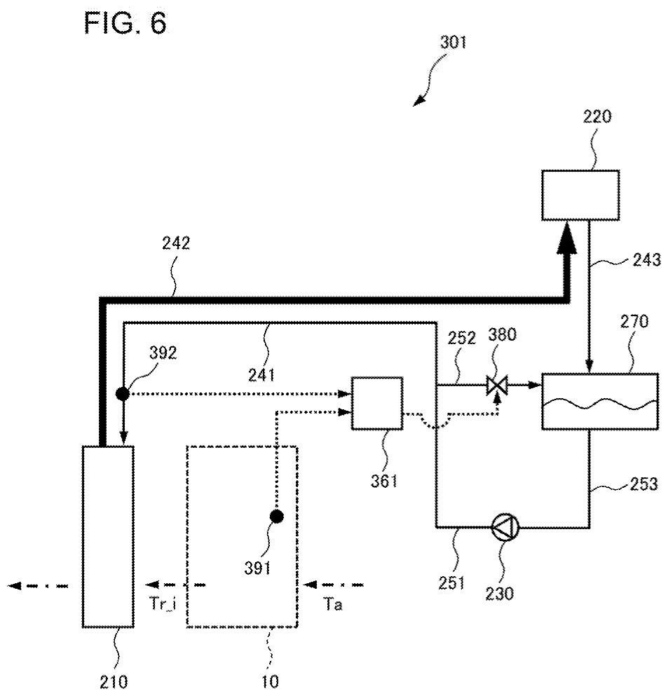

However, without applying only to this, it is possible to use, as the heat-receiving-side measured value, an output value of a power sensor to detect the amount of electricity used by the heat-generating source and an output value of a flow detection sensor to detect the flow rate of the heat-receiving-side refrigerant liquid. That is to say, as illustrated in FIG. 6, a phase-change cooling apparatus 301 according to the present example embodiment can be configured to include, instead of the temperature sensor 290, a power sensor 391 placed in a power supply and the like of the electronic equipment 10, and a flow detection sensor 392 placed in the second liquid pipe 241. Here, the flow detection sensor 392 can be any one of a flow rate sensor and a pressure sensor.

A controller 361 obtains, from the power sensor 391, power consumption of the electronic equipment 10. The controller 361 then controls a branched flow control valve 380 so as to supply the heat receiver 210 with a refrigerant liquid having a flow rate needed to transport the heat generation due to the power consumption. At this time, the controller 361 controls the branched flow control valve 380 monitoring the flow rate of the refrigerant liquid by the flow detection sensor 392.

The above-described configurations make it possible for the phase-change cooling apparatus 301 of the present example embodiment to supply the heat receiver 210 with the refrigerant liquid having the optimum flow rate according to the power consumption of the electronic equipment 10.

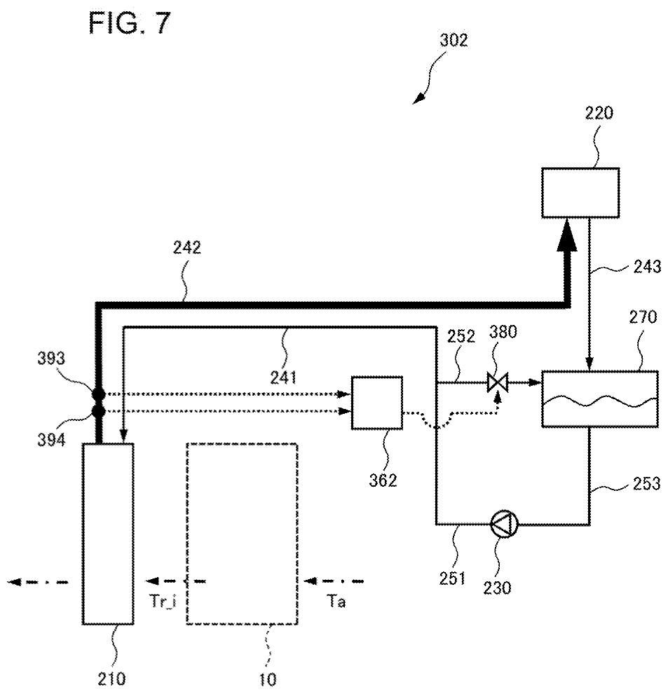

It is allowed to use, as the heat-receiving-side measured value, an output value of a steam-pipe temperature sensor to detect the temperature of the refrigerant vapor and an output value of a steam-pipe pressure sensor to detect the pressure of the refrigerant vapor. That is to say, as illustrated in FIG. 7, a phase-change cooling apparatus 302 according to the present example embodiment may be configured to include, instead of the temperature sensor 290, a steam-pipe temperature sensor 393 and a steam-pipe pressure sensor 394 that are placed in the steam pipe 242. In this case, a controller 362 calculates a degree of superheat of the refrigerant from the output values of the steam-pipe temperature sensor 393 and the steam-pipe pressure sensor 394, and controls a branched flow control valve 380 based on the calculated degree of superheat.

The above-described configurations make it possible to avoid the state that the refrigerant flowing through the steam pipe 242 becomes a two-phase flow in which vapor phase and liquid phase are mixed, according to the phase-change cooling apparatus 302 of the present example embodiment. Consequently, it is unnecessary to provide the steam pipe 242 with a structure to separate a vapor-phase refrigerant from a liquid-phase refrigerant.

### Fourth Example Embodiment

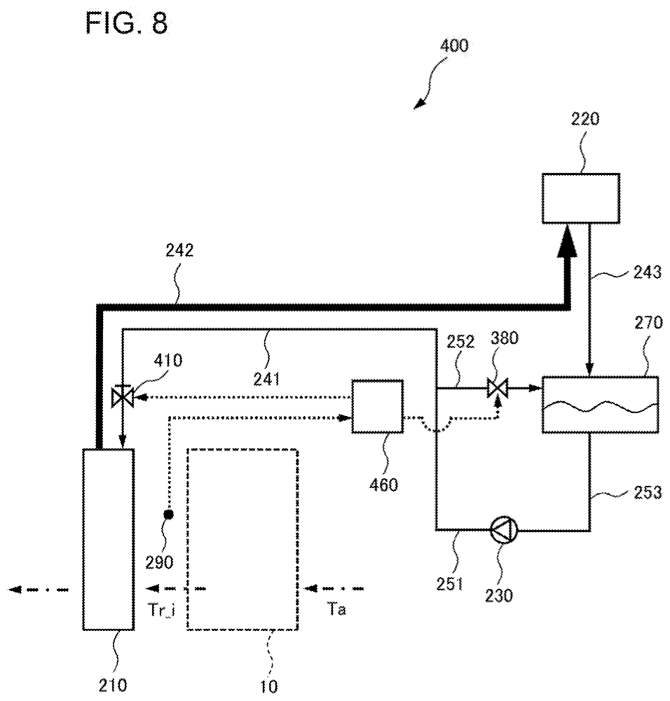

Next, a fourth example embodiment of the present invention will be described. FIG. 8 schematically illustrates a configuration of a phase-change cooling apparatus 400 according to the fourth example embodiment of the present invention. The identical reference sign is assigned to a configuration similar to that of the phase-change cooling apparatus 300 according to the third example embodiment, and its detailed description is not repeated.

The phase-change cooling apparatus 400 according to the present example embodiment includes a heat receiver (heat receiving means) 210, a heat radiator (heat radiating means) 220, a pump 230 serving as a refrigerant liquid driving means, a tank 270 serving as a refrigerant storing means, a branched flow control valve 380, and a controller (control means) 460.

The branched flow control valve 380 controls the flow rate of a branched refrigerant liquid that is at least part of the refrigerant liquid flowing away from the pump 230 toward the heat receiver 210. The branched flow control valve 380 is disposed on a fifth liquid pipe 252 in a second refrigerant flow path.

The phase-change cooling apparatus 400 of the present example embodiment further includes a heat-receiving flow control valve 410. The heat-receiving flow control valve 410 controls the flow rate of a heat-receiving-side refrigerant liquid that is a refrigerant liquid flowing into the heat receiver 210. The heat-receiving flow control valve 410 is disposed on a second liquid pipe 241 in a first refrigerant flow path. The first refrigerant flow path is composed of a first liquid pipe 251, the second liquid pipe 241, a steam pipe 242, a third liquid pipe 243, and a fourth liquid pipe 253.

The controller 460 controls the heat-receiving flow control valve 410 in addition to the branched flow control valve 380. At this time, the controller 460 is configured to control the heat-receiving flow control valve 410 based on a heat-receiving-side measured value regarding the amount of heat received from a heat-generating source. Here, the heat-receiving-side measured value can be an output value of a temperature sensor to detect the temperature of the exhaust air from the heat-generating source. In other words, the present example embodiment is configured to dispose a temperature sensor 290 on the exhaust side of the electronic equipment 10 serving as the heat-generating source.

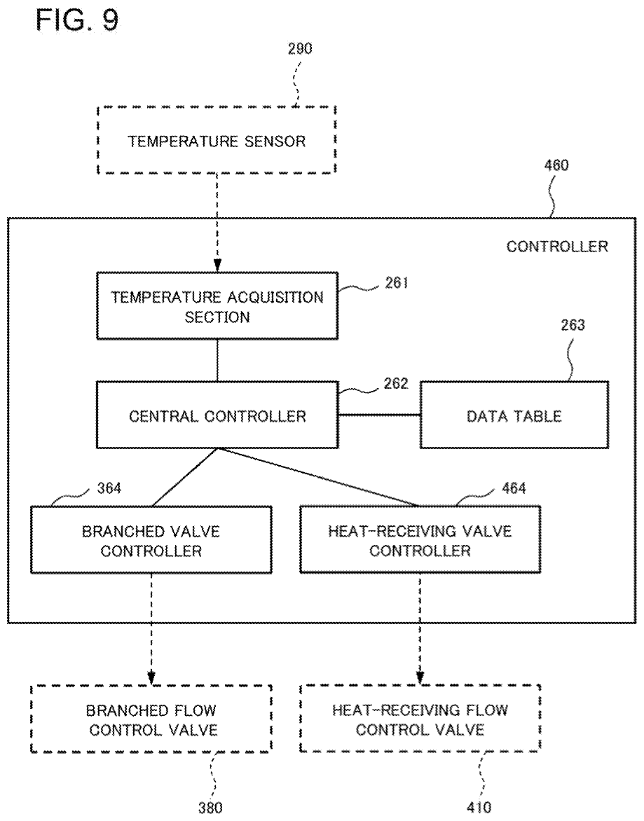

FIG. 9 illustrates a configuration of the controller 460 included in the phase-change cooling apparatus 400 according to the present example embodiment. The controller 460 includes a temperature acquisition section 261 configured to acquire the output value Tr_i from the temperature sensor 290, a central controller 262, a data table 263 in which a reference value of the output value of the temperature sensor 290 is recorded, and a branched valve controller 364 configured to control the branched flow control valve 380. The configurations so far are similar to those of the controller 360 included in the phase-change cooling apparatus 300 according to the third example embodiment. The controller 460 included in the phase-change cooling apparatus 400 according to the present example embodiment is configured to further include a heat-receiving valve controller 464 to control the heat-receiving flow control valve 410.

As mentioned above, the phase-change cooling apparatus 400 of the present example embodiment is configured to include the heat-receiving flow control valve 410. This makes it possible, even though the output value of the temperature sensor 290, that is, the heating value of the electronic equipment 10, has changed rapidly, to control the flow rate of the heat-receiving-side refrigerant liquid flowing into the heat receiver 210 following the rapid change.

As is the case with the phase-change cooling apparatuses according to the above-mentioned example embodiments, according to the phase-change cooling apparatus 400 of the present example embodiment, it is possible to avoid a decrease in cooling capacity immediately after startup even though a refrigerant liquid is circulated using a driving source.

In the above description, the phase-change cooling apparatus 400 is configured to include the branched flow control valve 380, and the controller 460 is configured to control the branched flow control valve 380. However, without applying only to this, as with the phase-change cooling apparatus 200 according to the second example embodiment (see FIG. 2), the constant flow valve 280 may be included instead of the branched flow control valve 380, and the controller may be configured to control the rotation frequency of the pump 230 and the heat-receiving flow control valve 410.

### Fifth Example Embodiment

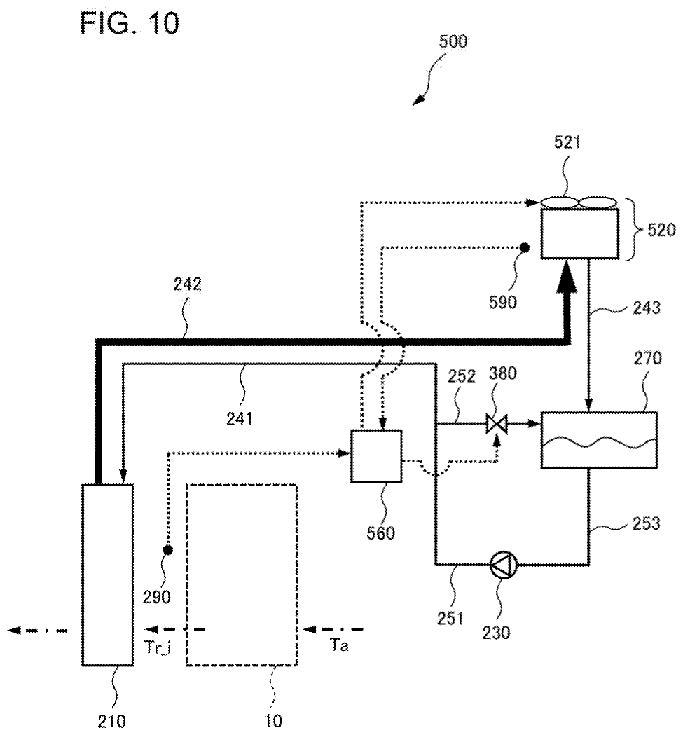

Next, a fifth example embodiment of the present invention will be described. FIG. 10 schematically illustrates a configuration of a phase-change cooling apparatus 500 according to the fifth example embodiment of the present invention. The identical reference sign is assigned to a configuration similar to that of the phase-change cooling apparatus 300 according to the third example embodiment, and its detailed description is not repeated.

The phase-change cooling apparatus 500 according to the present example embodiment includes a heat receiver (heat receiving means) 210, a heat radiator (heat radiating means) 520 including a blower 521, a pump 230 serving as a refrigerant liquid driving means, a tank 270 serving as a refrigerant storing means, a branched flow control valve 380, and a controller 560.

In the phase-change cooling apparatus 500 according to the present example embodiment, the controller 560 is configured to control the flow rate of a heat-receiving-side refrigerant liquid based on a heat-radiating-side measured value regarding the radiation performance of the heat radiator 520. In this case, the heat-radiating-side measured value can be an output value of an ambient temperature sensor to detect the ambient temperature of the heat radiator 520. In other words, the present example embodiment is configured to provide an ambient temperature sensor 590 for the periphery of the heat radiator 520.

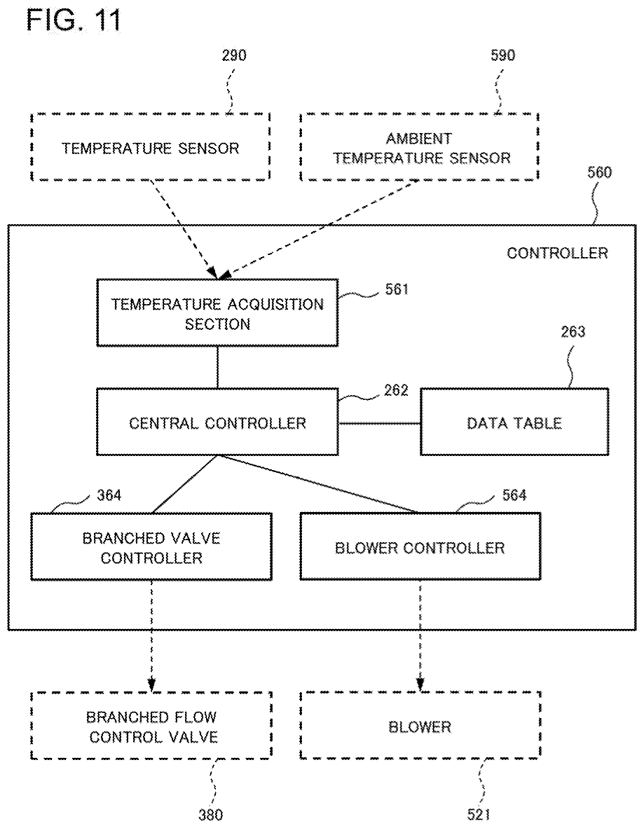

FIG. 11 illustrates a configuration of the controller 560 included in the phase-change cooling apparatus 500 according to the present example embodiment. The controller 560 includes a temperature acquisition section 561 configured to acquire output values from a temperature sensor 290 and the ambient temperature sensor 590, a central controller 262, a data table 263 in which reference values of the output values of the temperature sensor 290 and the ambient temperature sensor 590 are recorded. The controller 560 is configured to include further a branched valve controller 364 configured to control the branched flow control valve 380, and a blower controller 564 configured to control the blower 521 included in the heat radiator 520.

The above-mentioned configurations make it possible to vary the flow rate of the heat-receiving-side refrigerant liquid that is a refrigerant liquid flowing into the heat receiver 210 depending on changes in the radiation performance if the radiation performance of the heat radiator 520 changes, according to the phase-change cooling apparatus 500 of the present example embodiment. For example, if the heat radiator 520 is outdoor equipment, the cooling performance deteriorates as the outside air temperature is raised. If the cooling performance above a certain level cannot be obtained, the supply of the heat-receiving-side refrigerant liquid is cut off by increasing the opening degree of the branched flow control valve 380, and the operation of the blower 521 included in the outdoor equipment can be stopped. This makes it possible to save energy of the phase-change cooling apparatus 500.

In the above description, the phase-change cooling apparatus 500 is configured to include the branched flow control valve 380, and the controller 560 is configured to control the branched flow control valve 380. However, without applying only to this, as with the phase-change cooling apparatus 200 according to the second example embodiment (see FIG. 2), the constant flow valve 280 is included instead of the branched flow control valve 380, and the controller may be configured to control the rotation frequency of the pump 230. In this case, if the cooling performance above a certain level cannot be obtained, the controller can cut off the supply of the heat-receiving-side refrigerant liquid by stopping the rotation of the pump 230, and stop the operation of the blower 521 included in the outdoor equipment. Stopping operation of the pump 230 and the blower 521 makes it possible to save energy of the phase-change cooling apparatus 500.

Examples of the above-mentioned case in which the cooling performance above a certain level cannot be obtained, include a case in which a coefficient of performance (COP) drops to below one. Here, the coefficient of performance (COP) is a ratio of cooling performance to the sum of the power of a pump and the power of a blower (fan) included in outdoor equipment. In other words, it is expressed as follows: COP=cooling performance/(pump power+outdoor equipment fan power).

As is the case with the phase-change cooling apparatuses according to the above-mentioned example embodiments, according to the phase-change cooling apparatus 500 of the present example embodiment, it is possible to avoid a decrease in cooling capacity immediately after startup even though a refrigerant liquid is circulated using a driving source.

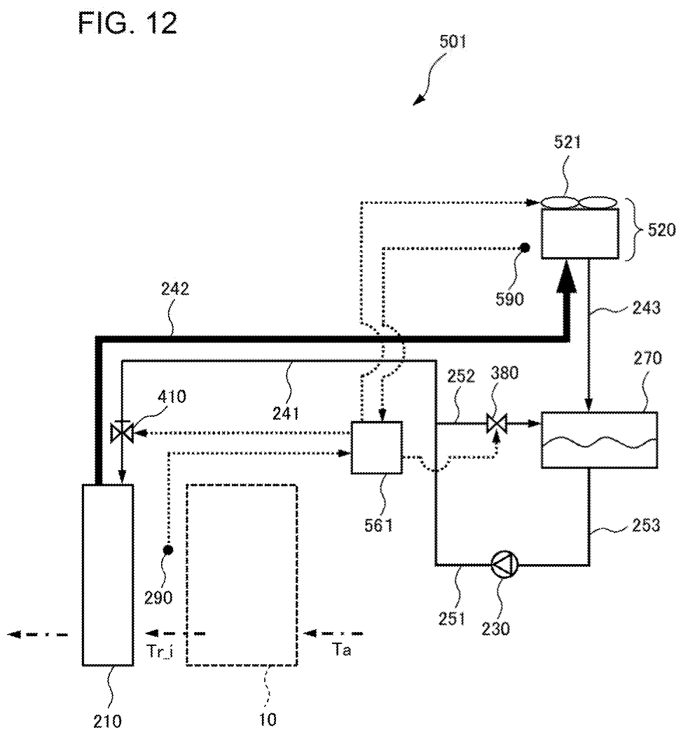

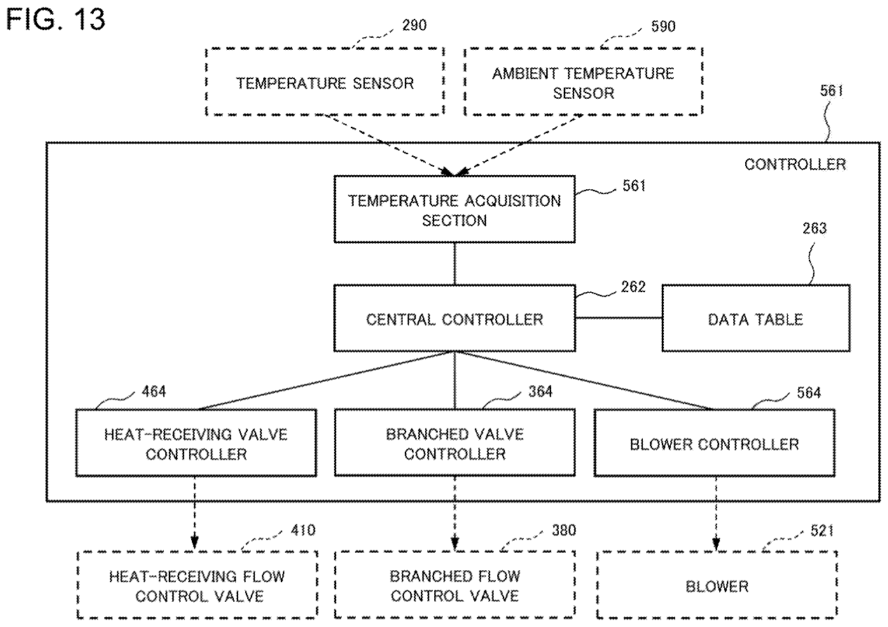

As with the phase-change cooling apparatus 400 described in the fourth example embodiment, the above-mentioned phase-change cooling apparatus 500 may be configured to include further the heat-receiving flow control valve 410 on the second liquid pipe 241. FIG. 12 illustrates a configuration of a phase-change cooling apparatus 501 in this case, and FIG. 13 illustrates a configuration of a controller 561 included in the phase-change cooling apparatus 501.

### Sixth Example Embodiment

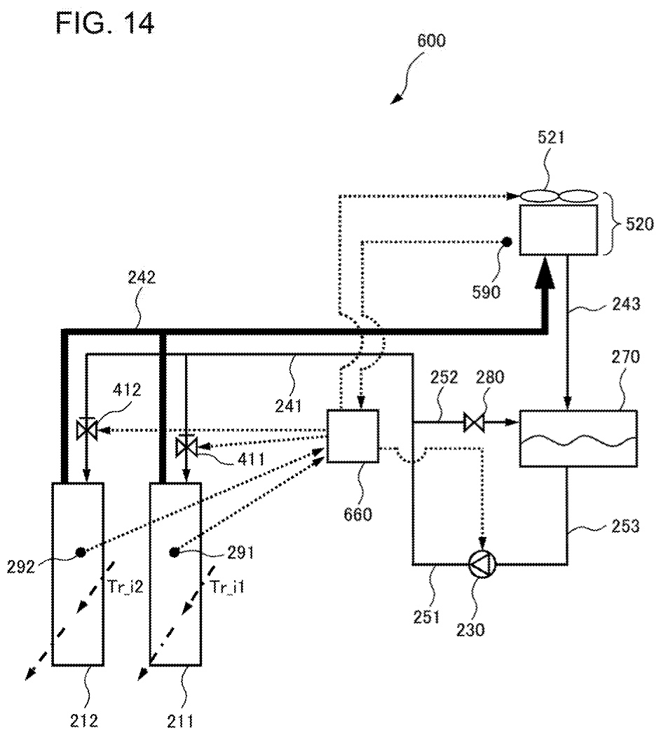

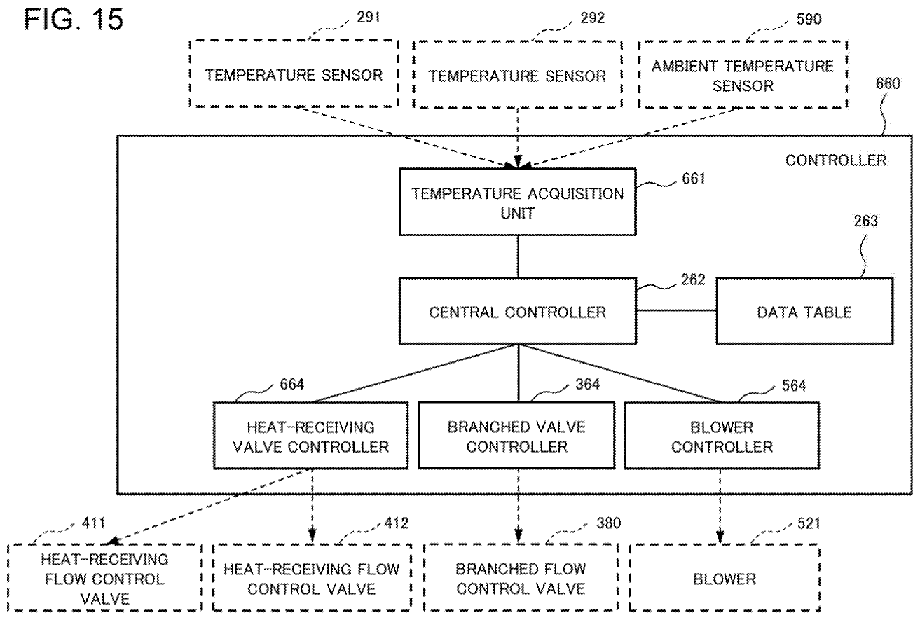

Next, a sixth example embodiment of the present invention will be described. In each of the above example embodiments, a phase-change cooling apparatus is described that includes one heat receiver and cools one piece of electronic equipment 10, as an example. Without limiting to this, by including a plurality of heat receivers, it becomes possible to cool plural pieces of electronic equipment 10. FIG. 14 illustrates a configuration of a phase-change cooling apparatus 600 according to the present example embodiment that has the above-described configuration, and FIG. 15 illustrates a configuration of a controller 660 included in the phase-change cooling apparatus 600. The phase-change cooling apparatus 600 including two heat receivers will be described below as an example.

As illustrated in FIG. 14, the phase-change cooling apparatus 600 according to the present example embodiment is configured to include two heat receivers 211 and 212, a heat radiator 520 including a blower 521, a pump 230, a tank 270, a constant flow valve 280, and a controller 660. The phase-change cooling apparatus 600 includes temperature sensors 291 and 292, and two heat-receiving flow control valves 411 and 412, corresponding to two heat receivers 211 and 212. The phase-change cooling apparatus 600 is also configured to include an ambient temperature sensor 590 on the periphery of the heat radiator 520.

As illustrated in FIG. 15, the controller 660 included in the phase-change cooling apparatus 600 is configured to include a temperature acquisition section 661, a central controller 262, a data table 263, a heat-receiving valve controller 664, a branched valve controller 364, and a blower controller 564. The temperature acquisition section 661 acquires respective output values of the two temperature sensors 291 and 292, and the ambient temperature sensor 590. The heat-receiving valve controller 664 controls two heat-receiving flow control valves 411 and 412. The other configurations of the phase-change cooling apparatus 600 according to the present example embodiment are similar to those described in each of the above-mentioned example embodiments; consequently, their descriptions are not repeated.

The above-described configurations make it possible, if one of the heat receivers is judged not to receive heat, from the output values of the temperature sensors 291 and 292, to close the heat-receiving flow control valve of the heat receiver without receiving heat, and to control the pump 230 to halve its flow rate, for example. This makes it possible to reduce the power consumption of the pump 230, and avoid it that the refrigerant liquid remains in the steam pipe 242. In this case, it is also possible to reduce by half the radiation capacity of the heat radiator 520; consequently, the power consumption of the blower (fan) can be reduced by decreasing the rotation frequency of the blower 521.

As is the case with the phase-change cooling apparatuses according to the above-mentioned example embodiments, according to the phase-change cooling apparatus 600 of the present example embodiment, it is possible to avoid a decrease in cooling capacity immediately after startup even though it is configured to include a plurality of heat receivers and circulate a refrigerant liquid using a driving source.

The whole or part of the example embodiments disclosed above can be described as, but not limited to, the following supplementary notes.

(Supplementary note 1) A phase-change cooling apparatus, comprising: heat receiving means for holding a refrigerant liquid to receive heat from a heat-generating source; heat radiating means for releasing heat of refrigerant vapor produced by evaporation of the refrigerant liquid in the heat receiving means and producing the refrigerant liquid; refrigerant liquid driving means for circulating the refrigerant liquid; a first refrigerant flow path in which the refrigerant liquid flowing away from the refrigerant liquid driving means circulates through the heat receiving means and the heat radiating means; a second refrigerant flow path of a flow path shortening the first refrigerant flow path in such a way that a branched refrigerant liquid being at least part of the refrigerant liquid flowing away from the refrigerant liquid driving means toward the heat receiving means circulates without passing through the heat receiving means and the heat radiating means; and control means for controlling a flow rate of a heat-receiving-side refrigerant liquid being a refrigerant liquid flowing into the heat receiving means based on a flow rate of the branched refrigerant liquid.

(Supplementary note 2) The phase-change cooling apparatus according to Supplementary note 1, wherein the second refrigerant flow path includes a constant flow valve configured to control a flow rate of the branched refrigerant liquid so as to be maintained constant, the refrigerant liquid driving means is a pump having a function that a flow rate varies according to a rotation frequency, and the control means controls a flow rate of the heat-receiving-side refrigerant liquid by controlling the rotation frequency.

(Supplementary note 3) The phase-change cooling apparatus according to Supplementary note 1, wherein the second refrigerant flow path includes a branched flow control valve configured to control a flow rate of the branched refrigerant liquid, and the control means controls a flow rate of the heat-receiving-side refrigerant liquid by controlling the branched flow control valve.

(Supplementary note 4) The phase-change cooling apparatus according to any one of Supplementary notes 1, 2, and 3, wherein the control means controls a flow rate of the heat-receiving-side refrigerant liquid based on a heat-receiving-side measured value regarding amount of heat received from the heat-generating source.

(Supplementary note 5) The phase-change cooling apparatus according to any one of Supplementary notes 1, 2, 3, and 4, wherein the control means controls a flow rate of the heat-receiving-side refrigerant liquid based on a heat-radiating-side measured value regarding radiation performance of the heat radiating means.

(Supplementary note 6) The phase-change cooling apparatus according to any one of Supplementary notes 1, 2, 3, 4, and 5, wherein the first refrigerant flow path includes a heat-receiving flow control valve configured to control a flow rate of the heat-receiving-side refrigerant liquid, and the control means controls the heat-receiving flow control valve based on a heat-receiving-side measured value regarding amount of heat received from the heat-generating source.

(Supplementary note 7) The phase-change cooling apparatus according to any one of Supplementary notes 1, 2, 3, 4, 5, and 6, further comprising refrigerant storing means for storing the refrigerant liquid in a flow path common to the first refrigerant flow path and the second refrigerant flow path.

(Supplementary note 8) A phase-change cooling method, comprising: circulating a refrigerant liquid flowing away from refrigerant liquid driving means in a first refrigerant flow path through heat receiving means and heat radiating means; circulating a branched refrigerant liquid being at least part of the refrigerant liquid flowing away from the refrigerant liquid driving means toward the heat receiving means through a second refrigerant flow path shortening the first refrigerant flow path, without passing through the heat receiving means and the heat radiating means; and controlling a flow rate of a heat-receiving-side refrigerant liquid being the refrigerant liquid flowing into the heat receiving means based on a flow rate of the branched refrigerant liquid.

(Supplementary note 9) The phase-change cooling method according to Supplementary note 8, wherein the controlling of the flow rate of the heat-receiving-side refrigerant liquid includes controlling a flow rate of the refrigerant liquid flowing away from the refrigerant liquid driving means, with a flow rate of the branched refrigerant liquid holding constant.

(Supplementary note 10) The phase-change cooling method according to Supplementary note 8, wherein the controlling of the flow rate of the heat-receiving-side refrigerant liquid includes controlling a flow rate of the branched refrigerant liquid.

(Supplementary note 11) The phase-change cooling apparatus according to Supplementary note 4 or 6, wherein the heat-receiving-side measured value is an output value of a temperature sensor to detect a temperature of exhaust air from the heat-generating source.

(Supplementary note 12) The phase-change cooling apparatus according to Supplementary note 4 or 6, wherein the heat-receiving-side measured value includes an output value of a power sensor to detect amount of electricity used by the heat-generating source and an output value of a flow detection sensor to detect a flow rate of the heat-receiving-side refrigerant liquid.

(Supplementary note 13) The phase-change cooling apparatus according to Supplementary note 4 or 6, wherein the heat-receiving-side measured value includes an output value of a steam-pipe temperature sensor to detect a temperature of the refrigerant vapor and an output value of a steam-pipe pressure sensor to detect pressure of the refrigerant vapor.

(Supplementary note 14) The phase-change cooling apparatus according to Supplementary note 5, wherein the heat-radiating-side measured value is an output value of an ambient temperature sensor to detect an ambient temperature of the heat radiating means.

(Supplementary note 15) The phase-change cooling method according to Supplementary note 9, wherein the controlling of the flow rate of the heat-receiving-side refrigerant liquid includes controlling a flow rate of the refrigerant liquid based on a heat-receiving-side measured value regarding amount of heat received from the heat-generating source.

(Supplementary note 16) The phase-change cooling method according to Supplementary note 10, wherein the controlling of the flow rate of the heat-receiving-side refrigerant liquid includes controlling a flow rate of the branched refrigerant liquid based on a heat-receiving-side measured value regarding amount of heat received from the heat-generating source.

(Supplementary note 17) The phase-change cooling method according to any one of Supplementary notes 8, 9, 10, 15, and 16, wherein the controlling the flow rate of the heat-receiving-side refrigerant liquid includes controlling based on a heat-radiating-side measured value regarding radiation performance of the heat radiating means.

(Supplementary note 18) The phase-change cooling method according to any one of Supplementary notes 8, 9, 10, 15, 16, and 17, further comprising controlling a flow rate of the heat-receiving-side refrigerant liquid based on a heat-receiving-side measured value regarding amount of heat received from the heat-generating source.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2017-139149, filed on Jul. 18, 2017, the disclosure of which is incorporated herein in its entirety by reference.

### REFERENCE SIGNS LIST

100, 200, 300, 301, 302, 400, 500, 501, 600 Phase-change cooling apparatus
110, 210, 211, 212 Heat receiver
120, 220, 520 Heat radiator
130 Refrigerant liquid driving section
140 First refrigerant flow path
150 Second refrigerant flow path
160, 260, 360, 361, 362, 460, 560, 561 Controller
230 Pump
241 Second liquid pipe
242 Steam pipe
243 Third liquid pipe
251 First liquid pipe
252 Fifth liquid pipe
253 Fourth liquid pipe
261, 561, 661 Temperature acquisition section
262 Central controller
263 Data table
264 Pump controller
270 Tank
280 Constant flow valve
290, 291, 292 Temperature sensor
364 Branched valve controller
380 Branched flow control valve
391 Power sensor
392 Flow detection sensor
393 Steam-pipe temperature sensor
394 Steam-pipe pressure sensor
410, 411, 412 Heat-receiving flow control valve
464, 664 Heat-receiving valve controller
521 Blower
564 Blower controller
590 Ambient temperature sensor
10 Electronic equipment

1. A phase-change cooling apparatus, comprising:
a heat receiver configured to hold a refrigerant liquid to receive heat from a heat-generating source;
a heat radiator configured to release heat of refrigerant vapor produced by evaporation of the refrigerant liquid in the heat receiver and produce the refrigerant liquid;
a refrigerant liquid driving section configured to circulate the refrigerant liquid;
a first refrigerant flow path in which the refrigerant liquid flowing away from the refrigerant liquid driving section circulates through the heat receiver and the heat radiator;
a second refrigerant flow path of a flow path shortening the first refrigerant flow path in such a way that a branched refrigerant liquid being at least part of the refrigerant liquid flowing away from the refrigerant liquid driving section toward the heat receiver circulates without passing through the heat receiver and the heat radiator; and
a controller configured to control a flow rate of a heat-receiving-side refrigerant liquid being a refrigerant liquid flowing into the heat receiver based on a flow rate of the branched refrigerant liquid.

2. The phase-change cooling apparatus according to claim 1, wherein
the second refrigerant flow path includes a constant flow valve configured to control a flow rate of the branched refrigerant liquid so as to be maintained constant,
the refrigerant liquid driving section is a pump having a function that a flow rate varies according to a rotation frequency, and
the controller controls a flow rate of the heat-receiving-side refrigerant liquid by controlling the rotation frequency.

3. The phase-change cooling apparatus according to claim 1, wherein
the second refrigerant flow path includes a branched flow control valve configured to control a flow rate of the branched refrigerant liquid, and
the controller controls a flow rate of the heat-receiving-side refrigerant liquid by controlling the branched flow control valve.

4. The phase-change cooling apparatus according to claim 1, wherein
the controller controls a flow rate of the heat-receiving-side refrigerant liquid based on a heat-receiving-side measured value regarding amount of heat received from the heat-generating source.

5. The phase-change cooling apparatus according to claim 1, wherein
the controller controls a flow rate of the heat-receiving-side refrigerant liquid based on a heat-radiating-side measured value regarding radiation performance of the heat radiator.

6. The phase-change cooling apparatus according to claim 1, wherein
the first refrigerant flow path includes a heat-receiving flow control valve configured to control a flow rate of the heat-receiving-side refrigerant liquid, and
the controller controls the heat-receiving flow control valve based on a heat-receiving-side measured value regarding amount of heat received from the heat-generating source.

7. The phase-change cooling apparatus according to claim 1, further comprising
a refrigerant storage configured to store the refrigerant liquid in a flow path common to the first refrigerant flow path and the second refrigerant flow path.

8. A phase-change cooling method, comprising:
circulating a refrigerant liquid flowing away from a refrigerant liquid driving section in a first refrigerant flow path through a heat receiver and a heat radiator;
circulating a branched refrigerant liquid being at least part of the refrigerant liquid flowing away from the refrigerant liquid driving section toward the heat receiver through a second refrigerant flow path shortening the first refrigerant flow path, without passing through the heat receiver and the heat radiator; and
controlling a flow rate of a heat-receiving-side refrigerant liquid being the refrigerant liquid flowing into the heat receiver based on a flow rate of the branched refrigerant liquid.

9. The phase-change cooling method according to claim 8, wherein
the controlling of the flow rate of the heat-receiving-side refrigerant liquid includes controlling a flow rate of the refrigerant liquid flowing away from the refrigerant liquid driving section, with a flow rate of the branched refrigerant liquid holding constant.

10. The phase-change cooling method according to claim 8, wherein
the controlling of the flow rate of the heat-receiving-side refrigerant liquid includes controlling a flow rate of the branched refrigerant liquid.

11. The phase-change cooling apparatus according to claim 4, wherein
the heat-receiving-side measured value is an output value of a temperature sensor to detect a temperature of exhaust air from the heat-generating source.

12. The phase-change cooling apparatus according to claim 4, wherein
the heat-receiving-side measured value includes an output value of a power sensor to detect amount of electricity used by the heat-generating source and an output value of a flow detection sensor to detect a flow rate of the heat-receiving-side refrigerant liquid.

13. The phase-change cooling apparatus according to claim 4, wherein
the heat-receiving-side measured value includes an output value of a steam-pipe temperature sensor to detect a temperature of the refrigerant vapor and an output value of a steam-pipe pressure sensor to detect pressure of the refrigerant vapor.

14. The phase-change cooling apparatus according to claim 5, wherein
the heat-radiating-side measured value is an output value of an ambient temperature sensor to detect an ambient temperature of the heat radiator.

15. The phase-change cooling method according to claim 9, wherein
the controlling of the flow rate of the heat-receiving-side refrigerant liquid includes controlling a flow rate of the refrigerant liquid based on a heat-receiving-side measured value regarding amount of heat received from the heat-generating source.

16. The phase-change cooling method according to claim 10, wherein
the controlling of the flow rate of the heat-receiving-side refrigerant liquid includes controlling a flow rate of the branched refrigerant liquid based on a heat-receiving-side measured value regarding amount of heat received from the heat-generating source.

17. The phase-change cooling method according to claim 8, wherein
the controlling the flow rate of the heat-receiving-side refrigerant liquid includes controlling based on a heat-radiating-side measured value regarding radiation performance of the heat radiator.

18. The phase-change cooling method according to claim 8, further comprising
controlling a flow rate of the heat-receiving-side refrigerant liquid based on a heat-receiving-side measured value regarding amount of heat received from the heat-generating source.

19. The phase-change cooling apparatus according to claim 2, wherein
the controller controls a flow rate of the heat-receiving-side refrigerant liquid based on a heat-receiving-side measured value regarding amount of heat received from the heat-generating source.

20. The phase-change cooling apparatus according to claim 3, wherein
the controller controls a flow rate of the heat-receiving-side refrigerant liquid based on a heat-receiving-side measured value regarding amount of heat received from the heat-generating source.
